(19) United States
(12) Patent Application Publication
(10) Pub. No.: US 2018/0167742 A1
(43) Pub. Date: Jun. 14, 2018

(54) TRANSDUCER PACKAGING

(71) Applicant: Cirrus Logic International Semiconductor Ltd., Edinburgh (GB)

(72) Inventors: Roberto BRIOSCHI, Austin, TX (US); Rkia ACHEHBOUNE, Edinburgh (GB); Marek Sebastian PIECHOCINSKI, Edinburgh (GB)

(73) Assignee: Cirrus Logic International Semiconductor Ltd., Edinburgh (GB)

(21) Appl. No.: 15/830,447

(22) Filed: Dec. 4, 2017

Related U.S. Application Data
(60) Provisional application No. 62/431,614, filed on Dec. 8, 2016.

(30) Foreign Application Priority Data
Jun. 29, 2017 (GB) 1710384.7

(51) Int. Cl. H04R 9/08; B81B 7/00; H04R 31/00

(52) U.S. Cl. CPC H04R 9/08; B81B 7/0061; H04R 31/00; H04R 2201/003; B81B 2203/0127; B81B 2207/03; B81C 2203/0109; B81B 2201/0257

(57) ABSTRACT

The applications describes lid designs for transducer packaging. The lid comprising at least one side wall which extends between a foot of the lid and an upper surface of the lid. One or more grooves are provided in a surface of the side wall which serve to resist the flow of molten solder on the surface of the lid.

### FIELD

The present invention relates to packaging for a MEMS transducer, such as a MEMS microphone. In particular the present application relates to a lid for a transducer package and to techniques for attaching the lid of a package to a substrate.

### BACKGROUND

Consumer electronics devices are continually getting smaller and, with advances in technology, are gaining ever-increasing performance and functionality. This is clearly evident in the technology used in consumer electronic products and especially, but not exclusively, portable products such as mobile phones, audio players, video players, personal digital assistants (PDAs), various wearable devices, mobile computing platforms such as laptop computers or tablets and/or games devices. Requirements of the mobile phone industry for example, are driving the components to become smaller with higher functionality and reduced cost. It is therefore desirable to integrate functions of electronic circuits together and combine them with transducer devices such as microphones and speakers.

Micro-electromechanical-system (MEMS) transducers, such as MEMS microphones are therefore finding application in many of these devices.

Microphone devices formed using MEMS fabrication processes typically comprise one or more membranes with electrodes for read-out/drive that are deposited on or within the membranes and/or a substrate or back-plate. In the case of MEMS pressure sensors and microphones, the electrical output signal read-out is usually accomplished by measuring a signal related to the capacitance between the electrodes.

To provide protection the MEMS transducer will be contained within a package. The package effectively encloses the MEMS transducer and can provide environmental protection and may also provide shielding for electromagnetic interference (EMI) or the like. The package also provides at least one external connection for outputting the electrical signal to downstream circuitry. For microphones and the like the package will typically have a sound port to allow transmission of sound waves to/from the transducer within the package and the transducer may be configured so that the flexible membrane is located between first and second volumes, i.e. spaces/cavities that may be filled with air (or some other gas suitable for transmission of acoustic waves), and which are sized sufficiently so that the transducer provides the desired acoustic response. The sound port acoustically couples to a first volume on one side of the transducer membrane, which may sometimes be referred to as a front volume. The second volume, sometimes referred to as a back volume, on the other side of the one of more membranes is generally required to allow the membrane to move freely in response to incident sound or pressure waves, and this back volume may be substantially sealed (although it will be appreciated by one skilled in the art that for MEMS microphones and the like the first and second volumes may be connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like).

Various package designs are known. For example, FIG. 1 illustrates a “lid-type” package 100. A MEMS transducer 101 is mounted to an upper surface of a package substrate 102. The package substrate 102 may be PCB (printed circuit board) or any other suitable material. A cover or “lid” 103 is located over the transducer 101 and is attached to the upper surface of the package substrate 102. The cover 103 may be a metallic lid. An aperture 104 in the substrate 102 provides a sound port and allows acoustic signals to enter the package. The MEMS transducer is mounted such that the flexible membrane of the transducer extends over the sound port. The package may also comprise an integrated circuit 105. The integrated circuit will typically be formed on a die of semiconductor material and will be customised for a particular application. The integrated circuit will be electrically connected to electrodes of the transducer 101 and an electrically conductive path will be provided between the integrated circuit and an electrical connection provided on an external surface of the package. The integrated circuit may provide bias to the transducer and may buffer or amplify a signal from the transducer.

The metal lid 103 is attached to the substrate 102 with either epoxy or solder paste. An effective bond between the foot of the lid and the substrate not only enables the physical adhesion of the lid to the substrate but also ensures back volume of the transducer 101 is acoustically sealed, thus ensuring the proper performance of the MEMS transducer.

In order to achieve a mechanically strong attachment, solder paste 106 is typically selected to be the most appropriate substance for bonding the lid 103 to the substrate 102. The solder paste is typically a tin alloy.

The soldering process is achieved with a well-known process known as reflow soldering in which the solder paste—a sticky mixture of powdered solder and flux—is used to join the lid and the substrate. According to known reflow soldering techniques, heat is applied to the solder paste to bring the solder above melting point, creating a liquid meniscus between the substrate and the foot of the metal lid. Finally, the joint is cooled in order to solidify the solder and thereby form a substantially permanent attachment between the lid and the substrate.

Once the solder has been heated above melting point and is in a liquid state, the molten solder will be able to flow or “creep” away from the initial position of the solder paste, thereby coating or “wetting” the surfaces it comes into contact with. However, it will be appreciated that if the degree of solder creeping is excessive, the amount of material contributable to forming the intended connection may be insufficient, thus compromising the mechanical integrity of the joint. Furthermore, voids or absences of solder material formed within the solder joint may also affect the acoustic performance of a transducer housed within the package. Solder creep that occurs inside the metal lid may contaminate the components within the package and may potentially short any electrical connections or wires within the package.

It is therefore desirable to provide a way of controlling and/or restricting the flow of molten solder during a reflow soldering process to attach two components of a package.

### SUMMARY

According to an example of an embodiment of a first aspect there is provided a lid for a transducer package, the lid comprising at least one side wall which extends between a foot of the lid and an upper surface of the lid. A plurality of grooves are provided in a surface of the side wall, each groove being provided at a different distance from the foot of the lid.

According an example of an embodiment of a second aspect there is provided lid for a transducer package, the lid comprising at least one side wall which extends between a foot of the lid and an upper surface of the lid. At least one groove is provided in a surface of the side wall. The groove extends to a depth of less than half the thickness of the side-wall and exhibits a height of less than twice the depth of the groove.

Each of the grooves provided in the surface of the side wall preferably extends widthways across the side wall of the lid.

Thus, according to an embodiment of a further aspect, there is provided a method of forming a lid for a transducer package, the method comprising: forming a plurality of concentric channels in the surface of a planar sheet of metal;

bending the planar sheet of metal to define a lid having an upper surface and a plurality of side walls, wherein the concentric channels form a plurality of grooves in a surface of one or more of the side walls.

### BRIEF DESCRIPTION OF DRAWINGS

For a better understanding of the present invention and to show how the same may be carried into effect, reference will now be made by way of example to the accompanying drawings in which:

FIG. 1 illustrates a previous example of a “lid-type” package;

FIG. 2 illustrates a cut-away section of a lid according to a first example;

FIG. 3 illustrates an enlarged partial view of the example shown in FIG. 2;

FIGS. 4a and 4b provide a schematic illustration from above and from the side of a possible method for making a lid;

FIG. 5 illustrates the contact angle θ of a liquid droplet with a planar surface;

FIGS. 6a and 6b illustrate solder wetting and solder non-wetting surfaces respectively;

FIG. 7a illustrates the wettability of a previously proposed package lid;

FIG. 7b illustrates the wettability of a lid according to an example of an embodiment;

FIGS. 8a to 8c illustrate a series of reflow process steps; and

FIGS. 9a to 9c illustrate a number of cross-section shapes for grooves.

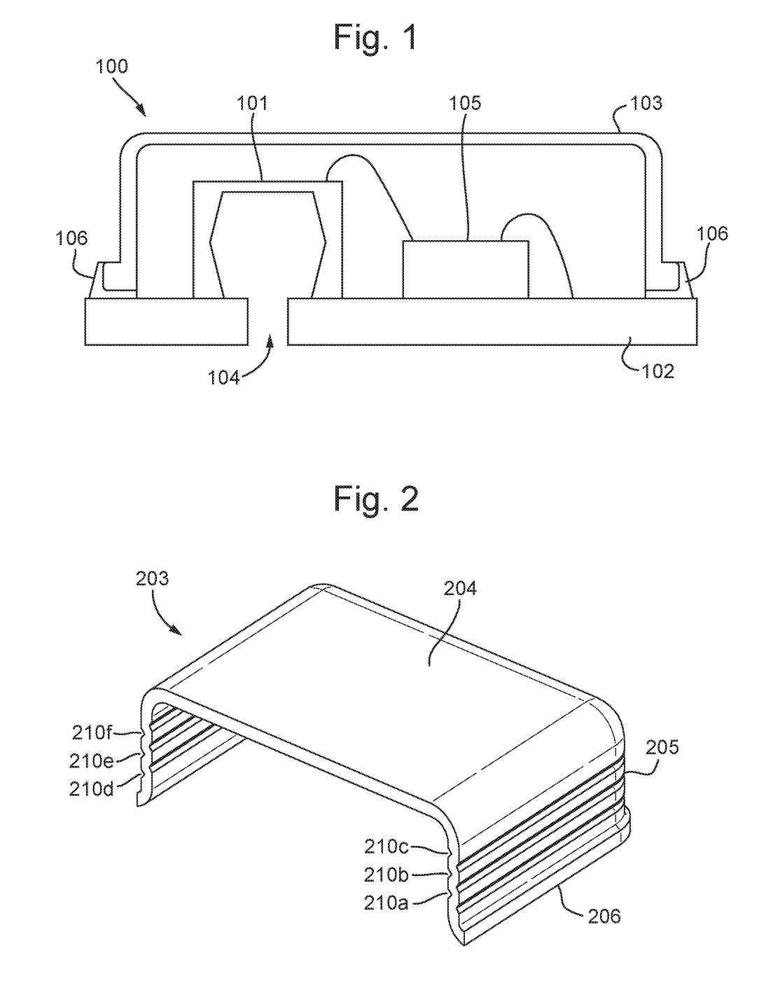

### DETAILED DESCRIPTION OF EMBODIMENTS

FIG. 2 shows a cut-away section of a lid 203 according to a first example of an embodiment. The lid 203 comprises substantially planar upper surface 204 and a plurality of side walls 205 which extend from a foot 206 of the lid to the upper surface 204. The sidewalls are provided with a plurality of grooves 210 which extend widthways, substantially parallel to the foot of the lid. In this example, the grooves are provided on both an inner and an outer surface of the sidewalls of the lid, though it will be appreciated that a plurality of grooves may be provided just on either the inner or the outer surface of one or more of the sidewalls. Thus, as shown in FIG. 2, an inner surface is provided with a first groove 210a which is provided at a first distance Xa from the foot, a second groove 210b which is provided at a second distance Xb from the foot and a third groove 210c which is provided at a third distance Xc from the foot. Furthermore, an outer surface is provided with a first groove 210d which is provided at a first distance Xd from the foot, a second groove 210e which is provided at a second distance Xe from the foot and a third groove 210f which is provided at a third distance Xf from the foot.

Thus, the grooves are provided at different distances from the foot of the lid. In the illustrated example, the grooves provided on the inner side are staggered with respect to the grooves provided on the outer side of the lid. This may be useful in that it ensures that the grooves on opposite surfaces do not intersect or extend too close to each other, which would potentially undermine the integrity or strength of the lid. However, examples are also envisaged in which grooves on the inner surface are located at substantially the same distances from the foot of the lid as grooves provided on the outer surface.

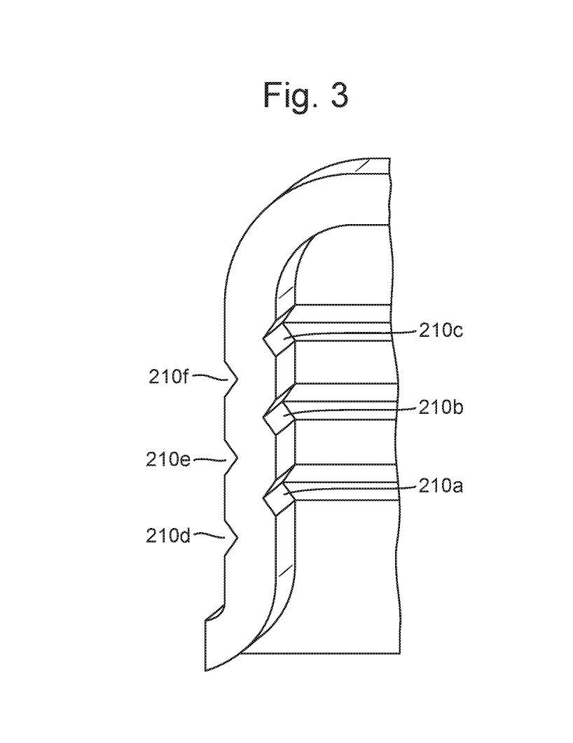

FIG. 3 shows an enlarged partial view of the example shown in FIG. 2.

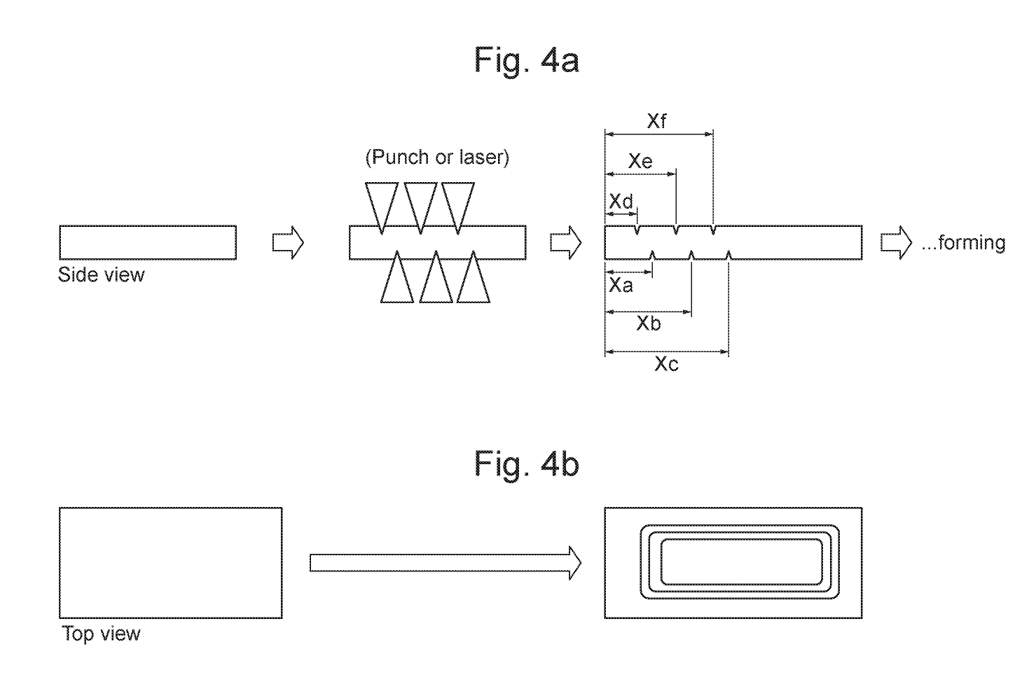

FIGS. 4a and 4b provide a schematic illustration from above and from the side of a possible method for making a lid according to an example of an embodiment. Specifically, a planar sheet of e.g. metal is provided as illustrated in the left hand side of FIGS. 4a and 4b. A plurality of concentric grooves are formed by punching the metal lid or by laser ablation. In a subsequent step (not illustrated) the planar sheet of metal is shaped or bent to form a lid having a plurality of sidewalls, wherein the grooves will be provided in the sidewalls of the lid.

Thus, according to an embodiment of a further aspect, there is provided a method of forming a lid for a transducer package, the method comprising: forming a plurality of concentric channels in the surface of a planar sheet of metal;

bending the planar sheet of metal to define a lid having an upper surface and a plurality of side walls, wherein the concentric channels form a plurality of grooves in a surface of one or more of the side walls.

During a soldering process for attaching the lid to e.g. a substrate to form a package for a transducer, molten solder may flow from the foot of the lid along a surface of the lid in a direction towards the upper surface of the lid. If the solder flows as far as the first groove provided closest to the foot of the lid, the groove will beneficially serve to inhibit, resist or slow the flow of the molten solder.

It is important to understand the way in which each of the grooves functions so as to inhibit the flow of the molten solder. In particular, since the grooves are preferably shallow the grooves do not provide a significant reservoir for containing the molten solder. Rather the grooves serve to alter the so-called “wettability” of the surface by altering the contact angle between the molten solder and the surface of the lid. For example, each groove may exhibit a depth of between ⅓ and ½ of the thickness of the side wall, and may exhibit a height of between 2 to 3 times the depth of the groove. For example, the depth of the groove may be around 25 microns and the height of the groove may be around 100 microns.

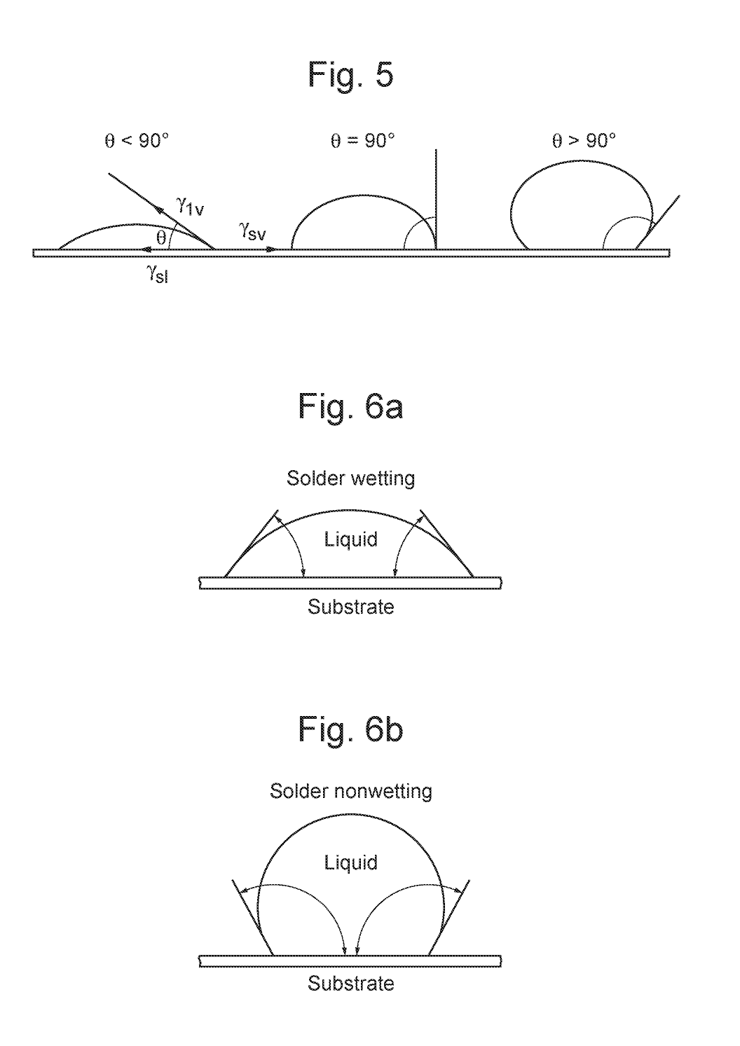

From consideration of the droplet profiles shown in FIG. 5, the contact angle θ can be defined as the angle formed by the intersection of the liquid-solid interface and the liquid-air interface. Thus, as shown in FIG. 6a, for a contact angle θ<90°, the surface can be considered to exhibit a hydrophilic (or solder-philic) characteristic. In other words, the conditions for wetting of the surface are favourable and the droplet will spread on the surface. However, as shown in FIG. 6b, for a contact angle θ>90°, the surface can be considered to show a solder-phobic characteristic. In other words, the conditions for wetting of the surface are unfavourable and the molten solder will tend to minimise its contact with the surface and form a compact droplet.

This theory can be used to explain the advantages associated with examples described herein.

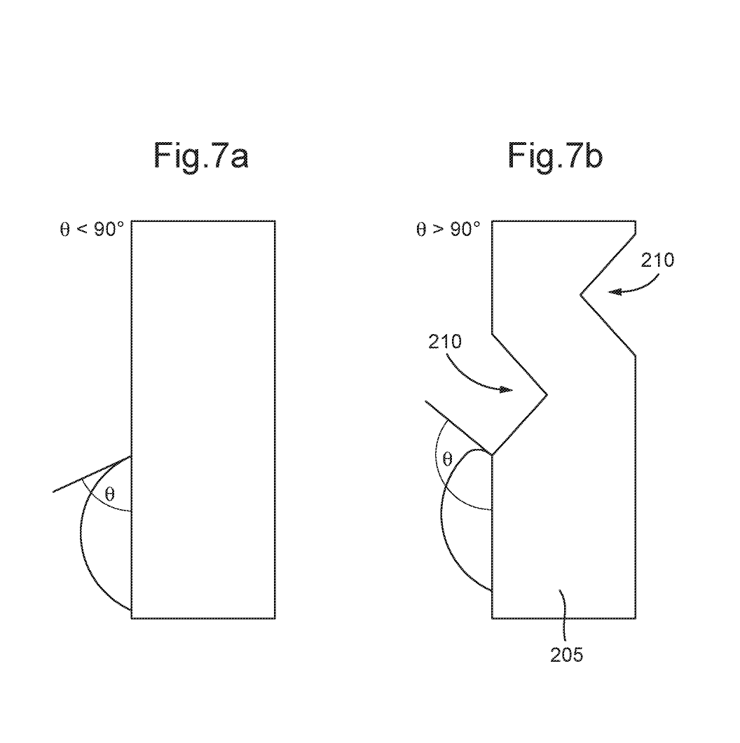

Thus, with reference to FIG. 7a which illustrates the wettability of a previously proposed package lid, it can been appreciated that the contact angle formed with respect to the surface of the lid is less than 90 degrees. Thus, the surface can be considered to be solder-philic and molten solder will potentially flow upwardly towards the upper surface of the lid. However, in contrast, and with reference to FIG. 7b which illustrates the wettability of a lid according to an example of an embodiment, the provision of a groove 210 in the surface of the lid sidewall 205 renders the surface resistant to the flow of solder beyond the lower edge of the groove.

It will be appreciated that although the groove will tend to resist the flow of solder below the lower edge of the groove, there may come a point at which the solder will nonetheless flow into the groove. This depends on various factors including e.g. the material properties of the lid and the solder, the temperature of the reflow process and the time for which the solder is molten and the number of reflow processes that take place.

Preferred examples exhibit a plurality of grooves disposed at successive intervals from the foot of the lid. This is advantageous in that if the solder does flow into and beyond the first groove, at least one additional groove is provided to act as a second or further barrier, each similarly serving to resist the flow of solder. This effectively widens the process conditions under which the lid can reliably be utilised and/or is particularly beneficial in circumstances where several soldering stages take place. Thus, the provision of multiple grooves potentially allows for a variety of operating conditions and variable to be accommodated whilst managing to contain or control solder creeping.

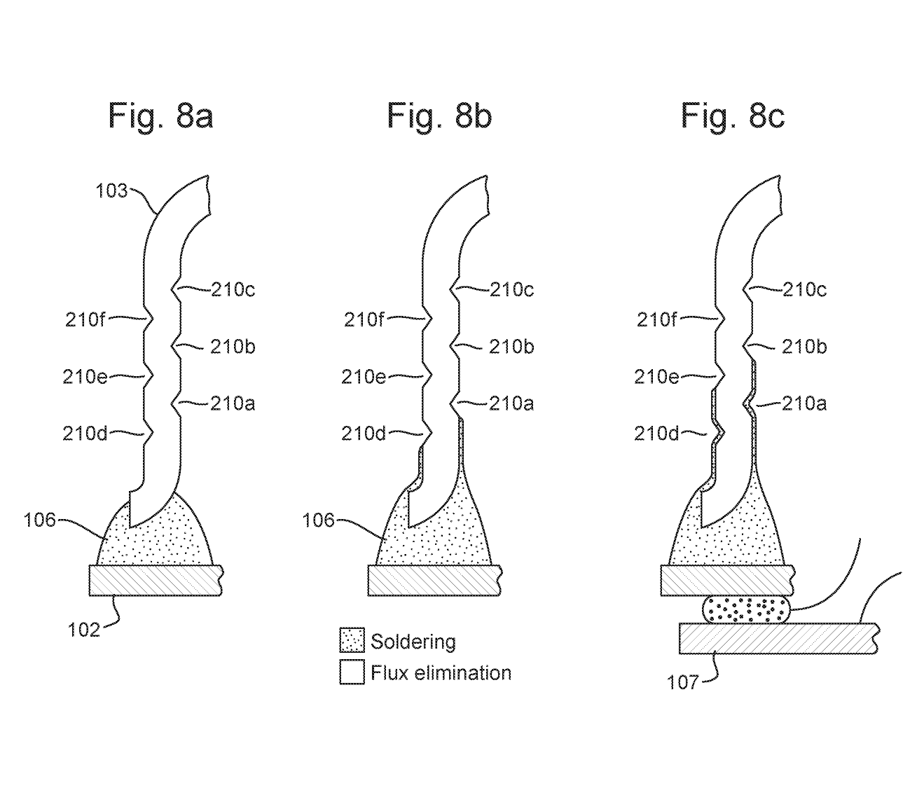

A lid forming part of a device such as a microphone will typically undergo more than one reflow process during manufacture/assembly. This is illustrated in FIG. 8. For example, as illustrated in FIG. 8a the solder paste 106a is applied at a joint between the foot of a lid 103 and a PCB substrate 102. As illustrated in FIG. 8b, a first reflow process causes the solder 106a to flow up the side wall of the lid. The molten solder encounters a first groove 210a on the inner surface of the side wall and a first groove 210d on the outer surface of the side wall. As illustrated, each of the first grooves serve to resist the continued flow of the solder beyond the lower edge of the respective groove. As illustrated in FIG. 8c, a second reflow process takes place in order to attach the substrate 102 to substrate/PCB of a host device, such as a phone. In this process, solder paste 106b is heated to form the required joint between the substrate 102 and the device substrate 107. Furthermore, the solder paste 106 also becomes heated and further solder creeps away from the joint region between the lid and the substrate. This results in solder flowing into and beyond the first grooves 210a and 210d before being eventually stopped by a second inner groove 210b and a second outer groove 210e.

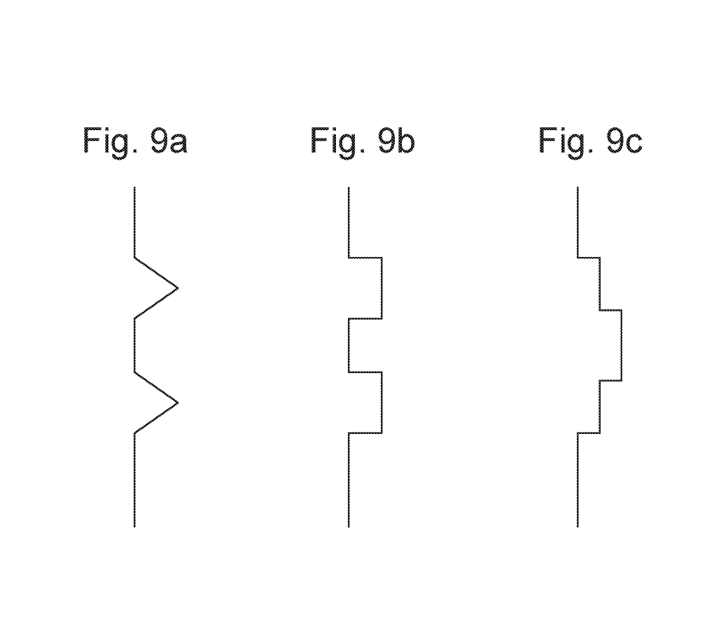

It will be appreciated that the, or one of the, grooves may exhibit a triangular cross-section as illustrated in FIG. 9a or a square or rectangular shaped cross section as illustrated in FIG. 9b. It is also envisaged that the grooves ma comprise one or more “steps” to give a stepped profile as illustrated in FIG. 9c. Such a configuration would further enhance the solder-phobic characteristic of the lid.

It will also be appreciated that the lid may or may not be plated.

A package comprising a lid as described herein may comprise a MEMS transducer. The MEMS transducer may comprise a capacitive sensor, for example a microphone.

Although the various examples describe packaging for a MEMS capacitive microphone, the examples are also applicable to packaging for any form of MEMS transducers other than microphones, for example pressure sensors or ultrasonic transmitters/receivers. A transducer element may comprise, for example, a microphone device comprising one or more membranes with electrodes for read-out/drive deposited on the membranes and/or a substrate or back-plate. In the case of MEMS pressure sensors and microphones, the electrical output signal may be obtained by measuring a signal related to the capacitance between the electrodes. However, it is noted that the embodiments are also intended to embrace the output signal being derived by monitoring piezo-resistive or piezo-electric elements or indeed a light source. The examples also intended embrace a transducer element being a capacitive output transducer, wherein a membrane is moved by electrostatic forces generated by varying a potential difference applied across the electrodes, including examples of output transducers where piezo-electric elements are manufactured using MEMS techniques and stimulated to cause motion in flexible members.

It will be appreciated that a transducer may comprise other components, for example electrodes, or a backplate structure, wherein the flexible membrane layer is supported with respect to said backplate structure. The backplate structure may comprises a plurality of holes through the backplate structure.

The MEMS transducer may be formed on a transducer die and may in some instances be integrated with at least some electronics for operation of the transducer.

A MEMS transducer according to the examples described here may further comprise readout circuitry such as a low-noise amplifier, voltage reference and charge pump for providing higher-voltage bias, analogue-to-digital conversion or output digital interface or more complex analogue and/or digital processing or circuitry, or other components. There may thus be provided a package having an integrated circuit comprising a MEMS transducer as described in any of the examples herein.

A lid as described herein may be provided to form a package. The package may comprise one or more sound ports. A MEMS transducer may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

An electronic device may be provided comprising a package having a lid according to any of the examples described herein. An electronic device may comprise, for example, at least one of: a portable device; a battery powered device; an audio device; a computing device; a communications device; a personal media player; a mobile telephone; a games device; and a voice controlled device.

It should be understood that the various relative terms upper, lower, top, bottom, underside, overlying, beneath, etc. that are used in the present description should not be in any way construed as limiting to any particular orientation of the lid or the package during any fabrication step and/or it orientation in any device or apparatus. Thus the relative terms shall be construed accordingly.

It should be noted that the above-mentioned examples illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A lid for a transducer package, the lid comprising at least one side wall which extends between a foot of the lid and an upper surface of the lid, wherein a plurality of grooves are provided in a surface of the side wall, each groove being provided at a different distance from the foot of the lid.

2. A lid for a transducer package as claimed in claim 1, wherein the surface of the side wall is an outer surface of the side wall.

3. A lid for a transducer package as claimed in claim 1, wherein the surface of the side wall is an inner surface of the side wall.

4. A lid for a transducer package as claimed in claim 1, wherein a plurality of grooves are provided in both an inner surface of the side wall and in an outer surface of the side wall.

5. A lid for a transducer package as claimed in claim 4, wherein the grooves provided on the inner surface of the side wall are staggered with respect to the grooves provided on the outer surface of the side wall.

6. A lid for a transducer package as claimed in claim 1, wherein the grooves extend substantially widthways across the side wall.

7. A lid for a transducer package as claimed in claim 1, wherein the grooves extend substantially in parallel with the foot of the lid.

8. A lid for a transducer package as claimed in claim 1, wherein the grooves exhibit a generally v-shaped cross section.

9. A lid for a transducer package as claimed in claim 1, wherein the grooves exhibit a substantially square or rectangular shaped cross-section

10. A lid for a transducer package as claimed in claim 1, wherein the lid is formed of metal.

11. A lid for a transducer package, the lid comprising at least one side wall which extends between a foot of the lid and an upper surface of the lid, wherein at least one groove is provided in a surface of the side wall, wherein the groove extends to a depth of less than half the thickness of the side-wall and exhibits a height of less than twice the depth of the groove.

12. A package for a MEMS transducer comprising a lid as claimed in claim 1, wherein the lid is mounted to a substrate to define a chamber of the package.

13. A package as claimed in claim 12, wherein the lid is mounted to the substrate by means of solder paste such as a tin alloy.

14. A package as claimed in any claim 12, further comprising a MEMS transducer provided within the chamber.

15. A package as claimed in claim 14, said MEMS transducer comprising a flexible membrane and being provided such that the flexible membrane overlies a sound port provided with the substrate.

16. A package as claimed in claim 15, wherein the sound port couples to a first volume provided beneath the flexible membrane and wherein a second volume is defined on the other side of the flexible membrane.

17. A package as claimed in claim 16, wherein said MEMS transducer is a MEMS microphone.

18. A package as claimed in claim 12, further comprising an integrated circuit, wherein said integrated circuit comprises one or more of analogue circuitry, digital circuitry or a programmable digital signal processor.

19. An electronic device comprising a package as claimed in claim 1, wherein said device is at least one of: a portable device; a battery power device; a computing device; a communications device; a gaming device; a mobile telephone; an earphone or in-ear hearing aid, a personal media player; a laptop, tablet or notebook computing device.

20. A method of forming a lid for a transducer package, the method comprising: forming a plurality of concentric channels in the surface of a planar sheet of metal; bending the planar sheet of metal to define a lid having an upper surface and a plurality of side walls, wherein the concentric channels form a plurality of grooves in a surface of one or more of the side walls.
